(19) United States
(12) Patent Application Publication
(10) Pub. No.: US 2025/0301790 A1
(43) Pub. Date: Sep. 25, 2025

(54) DEEP SOURCE DRAIN REGIONS AND BACKSIDE CONTACTS

(71) Applicant: INTERNATIONAL BUSINESS MACHINES CORPORATION, ARMONK, NY (US)

(72) Inventors: Lijuan Zou, Albany, NY (US); Tao Li, Slingerlands, NY (US); Ruilong Xie, Niskayuna, NY (US); Nicolas Jean Loubet, GUILDERLAND, NY (US)

(21) Appl. No.: 18/610,310

(22) Filed: Mar. 20, 2024

(51) Int. Cl. H01L 27/12

(52) U.S. Cl. CPC H10D 86/60; H10D 86/0214; H10D 86/441

(57) ABSTRACT

A nanosheet semiconductor structure including source drain regions arranged between channel nanosheets, where the source drain regions extend below a bottommost channel nanosheet into a backside dielectric layer, a liner surrounding at least a portion of the source drain regions, and backside contact structures in electrical contact with the source drain regions.

### BACKGROUND

The present invention generally relates to semiconductor structures, and more particularly to nanosheet transistor structures having a deep source drain regions and backside contacts.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include source drain regions arranged between channel nanosheets, where the source drain regions extend below a bottommost channel nanosheet into a backside dielectric layer, a liner surrounding at least a portion of the source drain regions, and backside contact structures in electrical contact with the source drain regions.

According to another embodiment of the present invention, a semiconductor structure is provided. The semiconductor structure may include a first source drain region arranged between first channel nanosheets, and a second source drain region arranged between second channel nanosheets, a first backside contact structure in electrical contact with the first source drain region and a second backside contact structure in electrical contact with the second source drain region, a first liner surrounding a portion of the first source drain region and a second liner surrounding a portion of the second source drain region; and where the first liner is arranged between and physically separates the first source drain region from the first channel nanosheets, and where the second source drain region directly contacts the second channel nanosheets.

According to another embodiment of the present invention, a semiconductor structure is provided. The semiconductor structure may include source drain regions arranged between channel nanosheets, where the source drain regions extend beneath the channel nanosheets into a backside dielectric layer, a liner arranged between and physically separating the source drain regions from the backside dielectric layer, and backside contact structures in electrical contact with the source drain regions.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after forming openings and liners according to an exemplary embodiment;

FIGS. 8, 9, and 10 are cross-sectional views of the semiconductor structure after recessing some of the liners according to an exemplary embodiment;

FIG. 11 is a cross-sectional view of the semiconductor structure after recessing some of the liners according to an alternate exemplary embodiment;

FIG. 12 is a cross-sectional view of the semiconductor structure after recessing some of the liners according to an alternate exemplary embodiment;

FIGS. 13, 14, and 15 are cross-sectional views of the semiconductor structure after forming source drain regions according to an exemplary embodiment;

FIGS. 16, 17, and 18 are cross-sectional views of the semiconductor structure after forming a dielectric layer according to an exemplary embodiment;

FIGS. 19, 20, and 21 are cross-sectional views of the semiconductor structure after forming source drain contacts, middle of line and back end of line, and securing a carrier wafer according to an exemplary embodiment;

FIGS. 22, 23, and 24, are cross-sectional views of the semiconductor structure after flipping the assembly and recessing the substrate according to an exemplary embodiment;

FIGS. 25, 26, and 27 are cross-sectional views of the semiconductor structure after removing and recessing remaining portions of the substrate according to an exemplary embodiment;

FIGS. 28, 29, and 30 are cross-sectional views of the semiconductor structure after forming a backside dielectric layer according to an exemplary embodiment;

FIGS. 31, 32, and 33 are cross-sectional views of the semiconductor structure after forming a mask and removing portions of the backside dielectric layer to form contact trenches according to an exemplary embodiment;

FIGS. 34, 35, and 36 are cross-sectional views of the semiconductor structure after removing portions of the liner according to an exemplary embodiment; and

FIGS. 37, 38, and 39 are cross-sectional views of the semiconductor structure after forming silicide layers, backside contact structures, and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact and placeholder fabrication techniques require relatively deep contact patterning. Doing so involves recessing or gouging the source drain regions and further increases the risk of shorting between backside source drain contacts and surrounding structures.

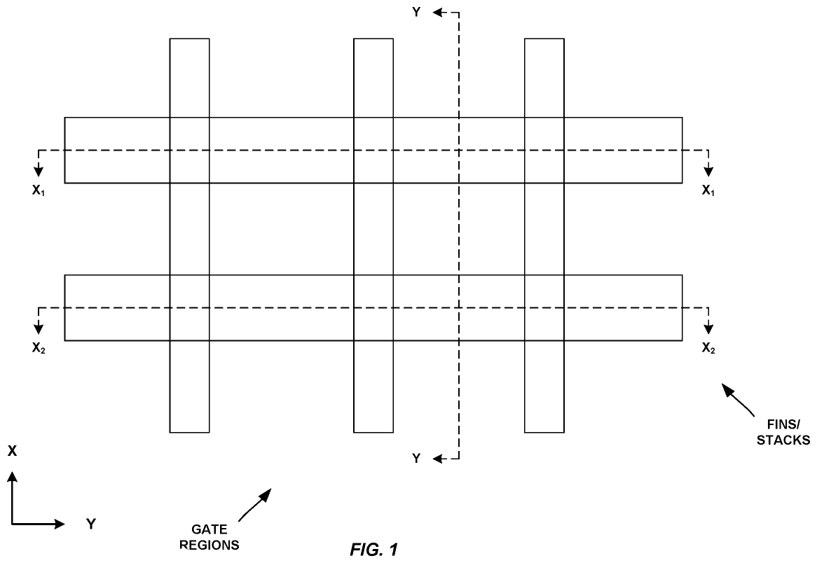

The present invention generally relates to semiconductor structures, and more particularly to nanosheet transistor structures having deep source drain regions and backside contacts. More specifically, the nanosheet transistor structures and associated method disclosed herein enable a novel solution for providing deep source drain regions and backside contacts. Exemplary embodiments of nanosheet transistor structures having deep source drain regions and backside contacts are described in detail below by referring to the accompanying drawings in FIGS. 1 to 39. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-39 represent cross section views oriented as indicated in FIG. 1

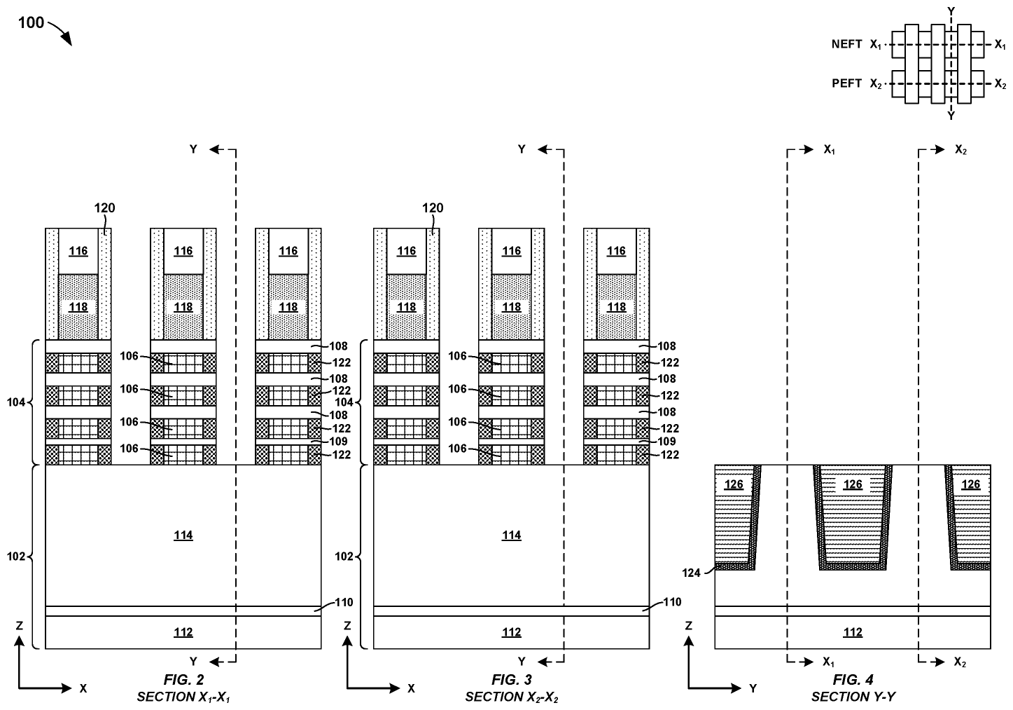

Referring now to FIGS. 2, 3, and 4, a structure 100 is shown during an intermediate step of a method of fabricating a nanosheet transistor structure according to an embodiment of the invention. FIG. 2 depicts a cross-sectional view of the structure 100 taken along line X₁-X₁, FIG. 3 depicts a cross-sectional view of the structure 100 taken along line X₂-X₂, and FIG. 4 depicts a cross-sectional view of the structure 100 taken along line Y-Y.

The structure 100 illustrated in FIGS. 2-4 includes an array of nanosheet stacks 104 formed on a substrate 102 in accordance with known techniques. Each nanosheet stack 104 includes an alternating series of silicon germanium (SiGe) sacrificial nanosheets 106 (hereinafter “sacrificial nanosheets 106”), silicon (Si) channel nanosheets 108 (hereinafter “channel nanosheets 108”), and silicon (Si) nanosheets 109 (hereinafter “silicon nanosheets 109”). Although only a limited number of nanosheet stacks and nanosheet layers are shown, embodiments explicitly contemplate any number of nanosheet stacks and nanosheet layers.

Unique to the embodiments disclosed herein, the silicon nanosheets 109 are substantially identical in composition to the channel nanosheets 108; however, the silicon nanosheets 109 are relatively thinner than the channel nanosheets 108. In at least one embodiment, the silicon nanosheets 109 have a thickness ranging from approximately 1-2 nm. The silicon nanosheets 109, located at the bottom of the nanosheet stacks 104, are intentionally thinner than the channel nanosheets 108 because they will be subsequently removed and not used as device channels in the final structure. Said differently, the silicon nanosheets 109 are sacrificial.

As such, the unique nanosheet stack 104 configurations of the present disclosure provide increase process margin for subsequent techniques, as described in more detail below. Specifically, the unique nanosheet stack 104 configurations of the present disclosure increases the space between the bottommost channel nanosheets 108 and a top surface of the substrate 102 all while maintaining uniform inner spacer height and width. Alternatively, designers might attempt to increase the space between the bottommost channel nanosheets 108 and the top surface of the substrate 102 without the thin silicon nanosheets 109; however, doing so would require fabrication of inner spacers of different sizes which will add complexity and issues during inner spacer formation.

For purposes of orientation, the substrate 102 is herein referred to as being on a “backside” of the structure 100 and the nanosheet stacks 104 are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent backside processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon.

In one or more embodiments, the nanosheet stacks 104 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, the channel nanosheets 108 of each nanosheet stacks 104 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The structure 100 further includes masks 116, sacrificial gates 118, and gate spacers 120.

The masks 116 are formed on top of a sacrificial gate material blanket deposited across the epitaxial nanosheet layers prior to forming the nanosheet stacks 104. Next a pattern created by the masks 116 is transferred into the sacrificial gate material to form the sacrificial gates 118 according to known techniques and as illustrated. The sacrificial gates 118 are commonly known by persons having skill in the art as dummy gates, and made from amorphous silicon (a-Si) or other selectively removable material.

After patterning the sacrificial gates 118, the gate spacers 120 are formed along sidewalls of the sacrificial gates 118 according to known techniques and as illustrated. The gate spacers 120 define the channel length and the source drain regions. The gate spacers 120 ultimately electrically insulate gates from source drain contact structures in the final structure. In at least one embodiment, the gate spacers 120 include silicon nitride, silicon boron nitride, silicon carbon nitride, silicon boron carbon nitride, or other known equivalents.

Next, a pattern created by both the masks 116 and the gate spacers 120 is transferred into the epitaxial nanosheet layers to form the nanosheet stacks 104 according to known techniques and as illustrated.

The structure 100 further includes inner spacers 122. The inner spacers 122 are disposed between alternate channels (108) after laterally recessing the sacrificial nanosheets 106 according to known techniques and as illustrated. The inner spacers 122 provide necessary electrical insulation between subsequently formed gates and source drain regions.

Finally, the structure 100 further includes shallow trench isolation regions (hereinafter “STI regions”) which extend partially into the substrate 102 as illustrated. In general, the STI regions may each include an isolation liner 124 and an isolation fill 126. For example, the isolation liner 124 is SiN, SiON, or SiOCN, and the isolation fill 126 is silicon oxide (SiO) or silicon nitride (SiN).

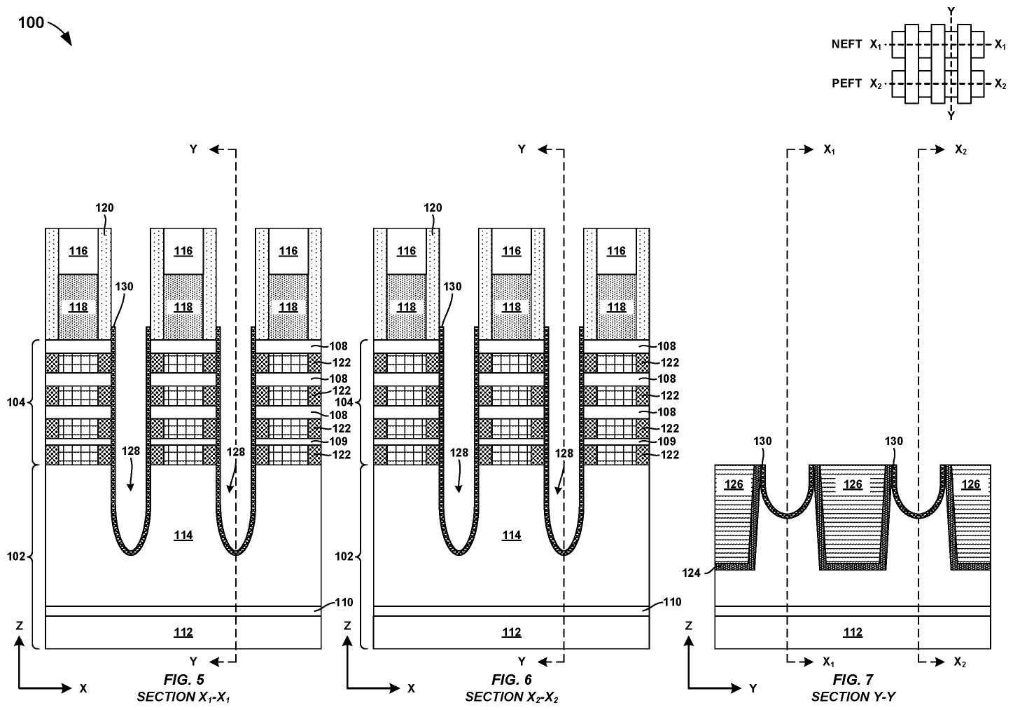

Referring now to FIGS. 5, 6, and 7, the structure 100 is shown after forming openings 128 and liners 130 according to an embodiment of the invention. FIG. 5 depicts a cross-sectional view of the structure 100 taken along line X₁-X₁, FIG. 6 depicts a cross-sectional view of the structure 100 taken along line X₂-X₂, and FIG. 7 depicts a cross-sectional view of the structure 100 taken along line Y-Y.

First, the substrate 102 is recessed to form the openings 128. More specifically, a directional anisotropic etching technique may be used to remove portions of the substrate 102 selective to the nanosheet stacks 104. In some embodiments, sidewalls of the nanosheet stacks 104 are protected with a sacrificial liner (not shown) during forming the openings 128, and then subsequently removed. For example, a reactive-ion-etching technique may be used to remove portions of the substrate 102, specifically portions of the top semiconductor layer 114, as illustrated.

Next, the liners 130 are formed by depositing or growing a compatible liner material from exposed semiconductor surfaces within the openings 128 according to known techniques. More specifically, the compatible liner material is epitaxially grown from the surfaces of the channel nanosheets 108 and the top semiconductor layer 114 exposed within the openings 128. In an embodiment, the compatible liner material is silicon germanium or amorphous silicon epitaxially grown from the surfaces of the channel nanosheets 108 and the top semiconductor layer 114 exposed within the openings 128. In all cases, the compatible liner material of the liners 130 should be capable of being removed selective to subsequently formed source drain regions.

Although the liners 130 are described and illustrated as lining a majority of the openings, they need only line exposed surfaces of the top semiconductor layer 114 to realize any benefit or advantage of the embodiments described herein. As such, if desired, a subsequent etching technique may be used to recess, and remove portions of the liners 130 without exposing the top semiconductor layer 114. Alternatively, a different technique or different material may be used to form the liners 130 only on surfaces of the top semiconductor layer 114.

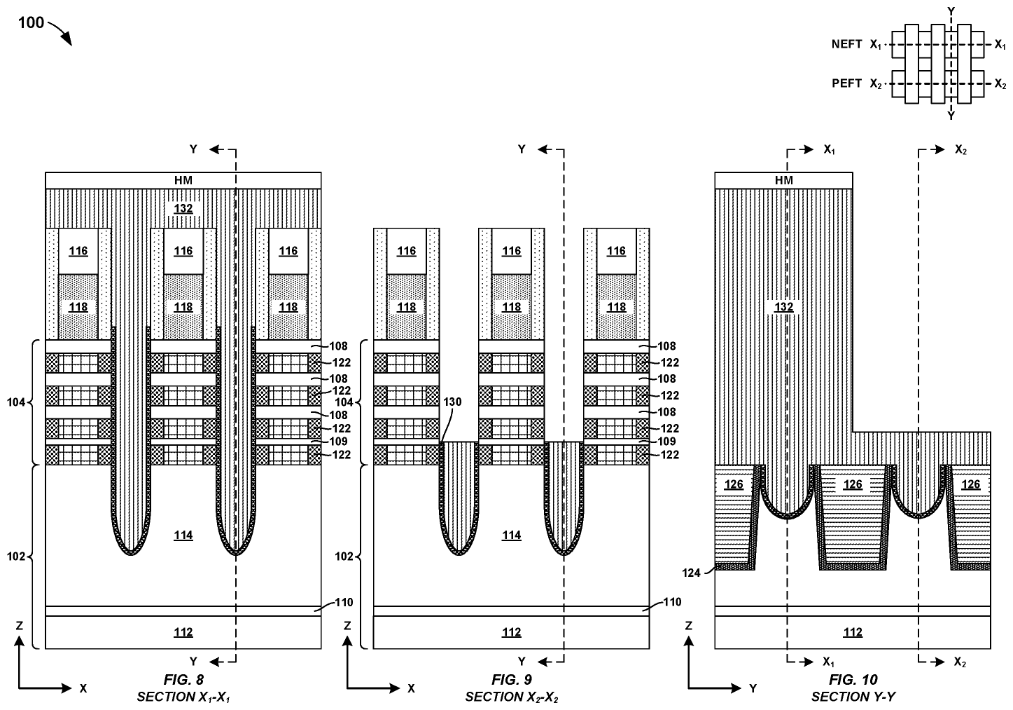

Referring now to FIGS. 8, 9, and 10, the structure 100 is shown after 130 according to an embodiment of the invention. FIG. 8 depicts a cross-sectional view of the structure 100 taken along line X₁-X₁, FIG. 9 depicts a cross-sectional view of the structure 100 taken along line X₂-X₂, and FIG. 10 depicts a cross-sectional view of the structure 100 taken along line Y-Y.

Some of the liners 130 are recessed according to known techniques. According to embodiments, for example, the liners 130 illustrated in FIG. 8 may be associated with PFET devices and the liners 130 illustrated in FIG. 9 may be associated with NFET devices. Here, the liners 130 associated with NFET devices (FIG. 9) are recessed while the liners 130 associated with PFET devices (FIG. 8).

First, a patterning layer 132 is deposited according to known techniques. The patterning layer 132 can be an organic planarization layer (OPL) or a layer of material that is capable of being planarized or etched by known techniques. In an embodiment, for example, the patterning layer 132 can be an amorphous carbon layer able to withstand subsequent processing temperatures. The patterning layer 132 can preferably have a thickness sufficient to fill the openings 128 and cover existing structures, as illustrated.

After depositing the patterning layer 132, a hard mask (HM) on top of the patterning layer 132 according to known techniques. Next, a dry etching technique is applied to pattern the hard mask (HM) and recess the patterning layer 132 according to known techniques. In doing so, the liners 130 associated with the NFET devices are also recessed. The patterning layer 132 and the liners 130 are recessed only in regions of the structure 100 associated with the NFET devices as illustrated and according to disclosed embodiments. The liners 130 will be formed from a single material across the structure 100, and that liner material will be compatible with either the PFET devices or the NFET devices, but not both. For example, silicon germanium liners (130) would generally be compatible with the formation of source drain regions associated with PFET devices (see FIG. 8), but are made from silicon germanium, generally incompatible with the formation of source drain regions associated with NFET devices (see FIG. 9). Therefore, the liners 130 must be recessed to accommodate the subsequent formation of source drains regions associated with the NFET devices.

According to embodiments, for example, a reactive-ion-etching technique may be first used to remove pattern the hard mask (HM) followed by a selective dry etch used to recess and remove portions of both the patterning layer 132 and the liners 130, as illustrated. It is further noted, the patterning layer 132 and the liners 130 may typically be recessed or removed using different etch chemistries according to known techniques. As such, the liners 130 will typically be recessed subsequent to recessing of the patterning layer 132, where the level of the patterning layer 132 is used as a benchmark or reference at which to subsequently recess the liners 130.

Unique to the disclosed embodiments, the relatively thin silicon nanosheets 109 provide a reasonably large process margin for recessing the liners 130. Since the silicon nanosheets 109 are intentionally not intended to be functioning device channels, the process margin for recessing the liners 130 is approximately the cumulative height of the silicon nanosheets 109 and two inner spacers 122. In contrast, the process margin for recessing the liners 130 in a typical nanosheet structure would be the height of only a single inner spacer 122. According to embodiments of the present disclosure, in all cases the liners 130 should be recessed at least below all the channel nanosheet 108, but without exposing the substrate 102.

If the liners 130 are not recessed deep enough, subsequent formation and growth of source drain regions associated with NFET devices could be prevented thereby limiting the number of active channels and negatively affecting device functionality and performance. For example, in such instances, the liners 130 could effectively block or cover some, or all, of the bottommost channel nanosheets 108 thereby effectively eliminating they from the NFET devices. Although, doing so may be desirable in some instances, the object of the present disclosure is a process flow which results in PFET devices and NFET devices each having a similar number of channels.

If the liners 130 are recessed too deep, and for example expose the top semiconductor layer 114, then subsequent techniques used to later remove the top semiconductor layer 114 could damage the already formed source drain regions thereby negatively affecting device functionality and performance. For example, the etching techniques used to remove the substrate during backside processing would attack any exposed portions of the source drain regions resulting from recessing the liners 130 too deep. The liners 130 are specifically configured to protect the source drain regions during subsequent substrate removal.

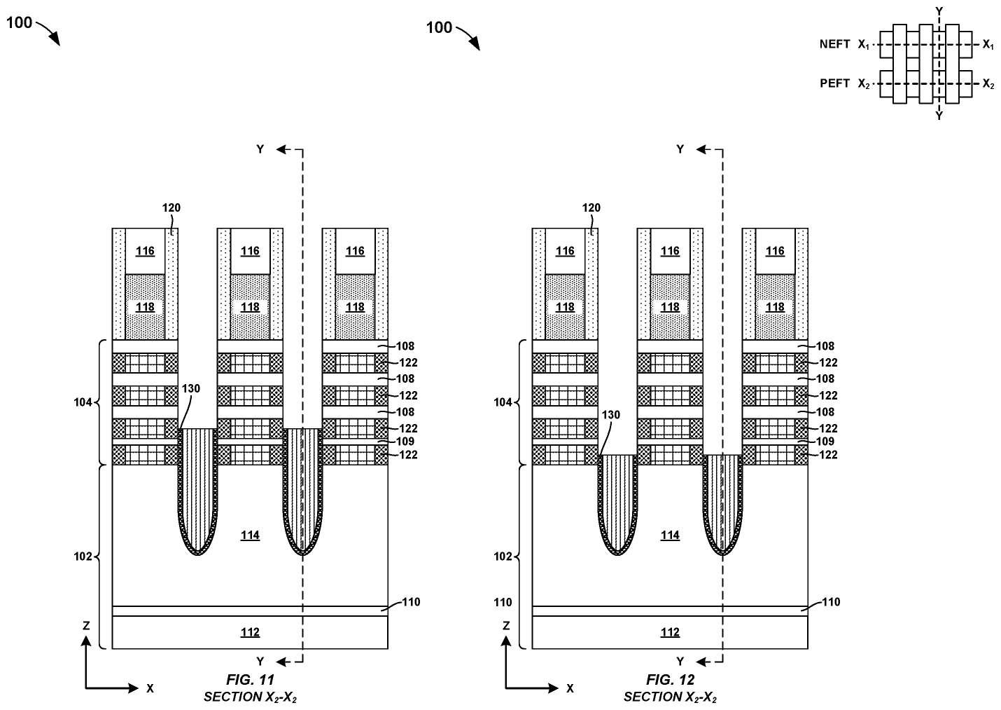

Referring now to FIGS. 11 and 12, the structure 100 is shown after recessing some of the liners 130 according to alternative embodiments of the invention. FIG. 11 depicts a cross-sectional view of the structure 100 taken along line X₂-X₂ and FIG. 12 depicts a cross-sectional view of the structure 100 taken along line X₂-X₂.

With specific reference to FIG. 11 and according to an alternative embodiment, the liners 130 are recessed less than described above with respect to FIG. 9. More specifically, the liners 30 of the embodiment illustrated in FIG. 11 are recessed at least below the channel nanosheets 108, but not below the silicon nanosheet 109. Said differently, after recessing the liners 130, all of the channel nanosheets 108 will be exposed, and the silicon nanosheet 109 will remain covered.

With specific reference to FIG. 12 and according to an alternative embodiment, the liners 130 are recessed greater than described above with respect to FIG. 9. More specifically, the liners 30 of the embodiment illustrated in FIG. 12 are recessed at least below the silicon nanosheet 109, but without exposing any portion of the substrate 102.

FIGS. 11 and 12 illustrate the increased process margin afforded by the unique nanosheet stack 104 configurations having a silicon nanosheet 109 thinner than the channel nanosheets 108, as described above. Typically, the process margin would be approximately equal to the height of a single inner spacer 122, or about 8 nm. According to embodiments of the present disclosure, the process margin is more than double the height of a single inner spacer 122, or about 16 nm or more.

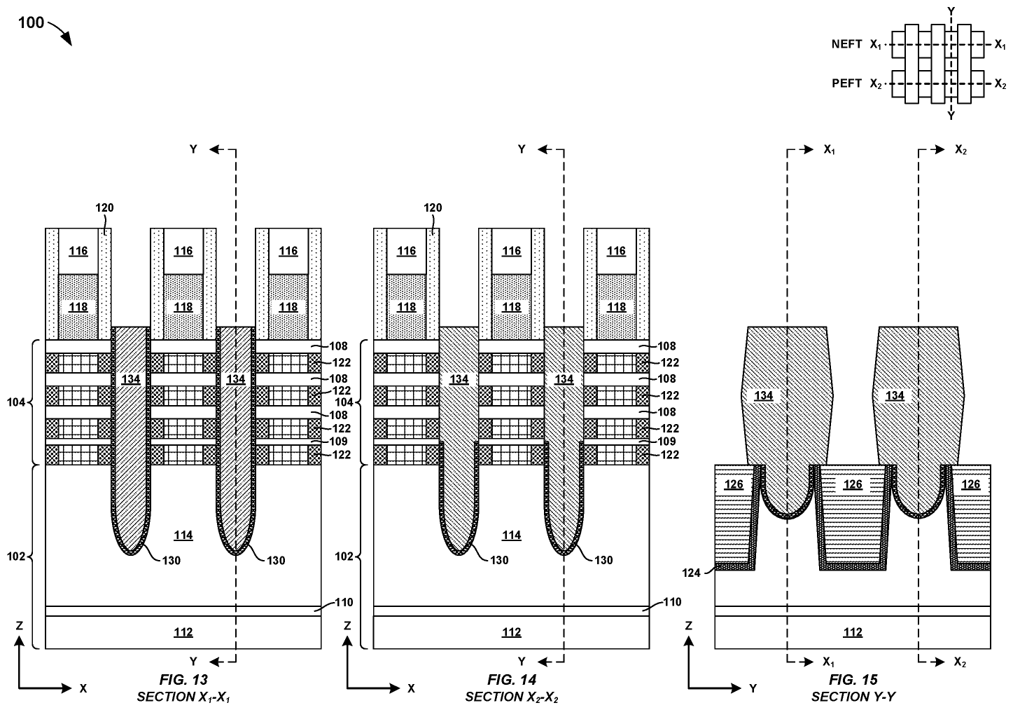

Referring now to FIGS. 13, 14, and 15, the structure 100 is shown after forming source drain regions 134 according to an embodiment of the invention. FIG. 13 depicts a cross-sectional view of the structure 100 taken along line X₁-X₁, FIG. 14 depicts a cross-sectional view of the structure 100 taken along line X₂-X₂, and FIG. 15 depicts a cross-sectional view of the structure 100 taken along line Y-Y.

First, remaining portions of the hard mask (HM) and the patterning layer 132 are removed according to known techniques. Next, the source drain regions 134 are formed within the openings 128 directly on top of the liners 130 according to known techniques. Specifically, the source drain regions 134 are disposed between adjacent nanosheet stacks 104 in direct contact with exposed ends of the channel nanosheets 108.

The source drain regions 134 are formed using an epitaxial layer growth process on the exposed ends of the channel nanosheets 108 according to known techniques. Typically, in-situ doping is used to dope the source drain regions 134, thereby creating the necessary junctions. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a p-type piece of silicon, rich in holes, and an n-type piece of silicon, rich in electrons. N-type and p-type devices are formed by implanting different types of dopants to selected regions of the device to form the necessary junction(s). N-type devices can be formed by implanting arsenic (As) or phosphorous (P), and p-type devices can be formed by implanting boron (B).

According to embodiments of the present invention, for example, the source drain regions 134 illustrated in FIG. 13 may be associated with PFET devices and the source drain regions 134 illustrated in FIG. 14 may be associated with NFET devices. In most cases, the source drain regions 134 associated with PFET devices are made from different materials than those source drain regions 134 associated with NFET devices. In an embodiment, for example, the source drain regions 134 associated with PFET devices (FIG. 13) are made from silicon germanium doped with p-type dopants (e.g., boron or gallium), and the source drain regions 134 associated with NFET devices (FIG. 14) are made from silicon doped with n-type dopants (e.g., phosphorus or arsenic).

Unique to the disclosed embodiments, the liners 130 associated with the PFET devices, and illustrated in FIG. 13, physically separate all of the channel nanosheets 108 from the source drain regions 134. As such, the source drains of FIG. 13 are epitaxially grown from the liners 130 according to known techniques. In contrast and unique to the disclosed embodiments, the liners 130 associated with the NFET devices, and illustrated in FIG. 14, do not physically separate all of the channel nanosheets 108 from the source drain regions 134. As such, the source drains of FIG. 14 are epitaxially grown from both the liners 130 and exposed ends of the channel nanosheets 108 according to known techniques.

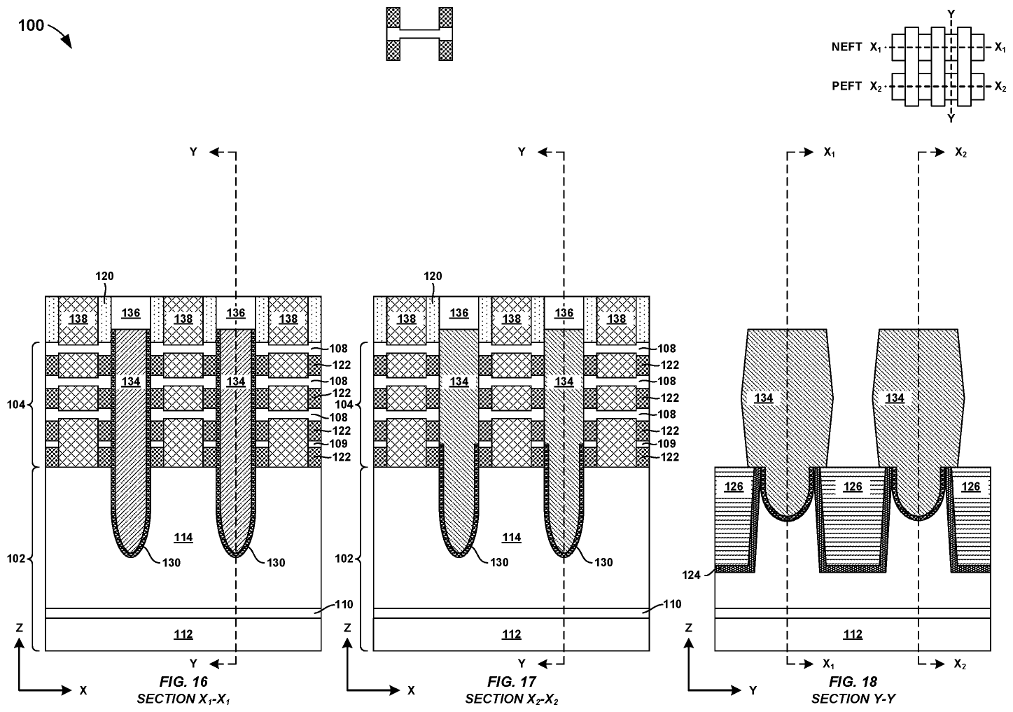

Referring now to FIGS. 16, 17, and 18, the structure 100 is shown after forming a dielectric layer 136 according to an embodiment of the invention. FIG. 16 depicts a cross-sectional view of the structure 100 taken along line X₁-X₁, FIG. 17 depicts a cross-sectional view of the structure 100 taken along line X₂-X₂, and FIG. 18 depicts a cross-sectional view of the structure 100 taken along line Y-Y.

First, the dielectric layer 136 is formed by blanket depositing an interlayer dielectric material over the structure 100 according to known techniques. Specifically, the dielectric layer 136 is formed on the source drain regions 134 and substantially fills the remaining space between the gate spacers 120, as illustrated. After, the dielectric layer 136 can be polished using known techniques until a topmost surface of the dielectric layer 136 is flush, or substantially flush, with topmost surfaces of the masks 116 and the gate spacers 120, as illustrated.

The dielectric layer 136 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. In another embodiment, a self-planarizing material such as a spin-on glass (SOG) or a spin-on low-k dielectric material such as SiLK™ can be used as the dielectric layer 136. Using a self-planarizing dielectric material as the dielectric layer 136 can avoid the need to perform a subsequent planarizing step.

After the dielectric layer 136 is formed, the structure 100 is polished according to known techniques, such as, for example, chemical mechanical polishing techniques. Specifically, the dielectric layer 136, the gate spacers 120, and the hard mask (HM) are polished until a topmost surface of the dielectric layer 136 is flush, or substantially flush, with topmost surfaces of the gate spacers 120 and the sacrificial gates 118.

With continued reference to FIGS. 16-18, the structure 100 is shown after selectively removing the sacrificial gates 118, the sacrificial nanosheets 106, and the silicon nanosheets 109, and subsequently forming gate structures 138 according to an embodiment of the invention.

Next, the sacrificial gates 118 and the sacrificial nanosheets 106 are selectively removed according to known techniques. First, the sacrificial gates 118 are etched and removed selective to the gate spacers 120 and the nanosheet stacks 104 according to known techniques. Next, the sacrificial nanosheets 106 are etched and removed selective to the channel nanosheets 108 and the inner spacers 122 according to known techniques. Doing so is made possible by the different concentrations of germanium. In this case, the layers with germanium are removed selective to layers without germanium.

Next, exposed portions of the silicon nanosheets 109 are removed according to known techniques. More specifically the silicon nanosheets 109 are removed selective to the inner spacers 122 and the gate spacers 120. Since the silicon nanosheets 109 are substantially the same material as the channel nanosheets 108, the selective etch chemistry chosen to remove the silicon nanosheets 109 will also etch, or trim, the channel nanosheets 108. Furthermore, since the channel nanosheets 108 are thicker than the silicon nanosheets 109, the exposed portions of the silicon nanosheets 109 may be completely removed without completely removing the channel nanosheets 108. In fact, according to disclosed embodiments, etching continues only until the silicon nanosheets 109 are removed in an effort to substantially preserve the channel nanosheets 108. After etching, exposed portions of the channel nanosheets 108 will have a reduced thickness, and small portions of the silicon nanosheets 109 will remain sandwiched between the inner spacers 122, as illustrated.

Next, the gate structures 138 are formed according to known techniques. First, a gate dielectric (not shown) is conformally deposited directly on exposed surfaces of the structure 100 within the gate cavities or openings and spaces left by removing the sacrificial gates 118 and the sacrificial nanosheets 106 according to known techniques. For example, the gate dielectric is conformally deposited on exposed surfaces of the channel nanosheets 108 and the inner spacers 122.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium carbon (TiC), titanium aluminum (TiAl), titanium aluminum carbon (TiAlC), or multilayered combinations thereof. In some embodiments, the work function metal can include an NFET gate metal. In other embodiments, the work function metal can include a PFET gate metal. When multiple gate cavities are formed, as illustrated herein, embodiments of the present invention explicitly contemplate forming an NFET in at least one of the gate cavities and a PFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

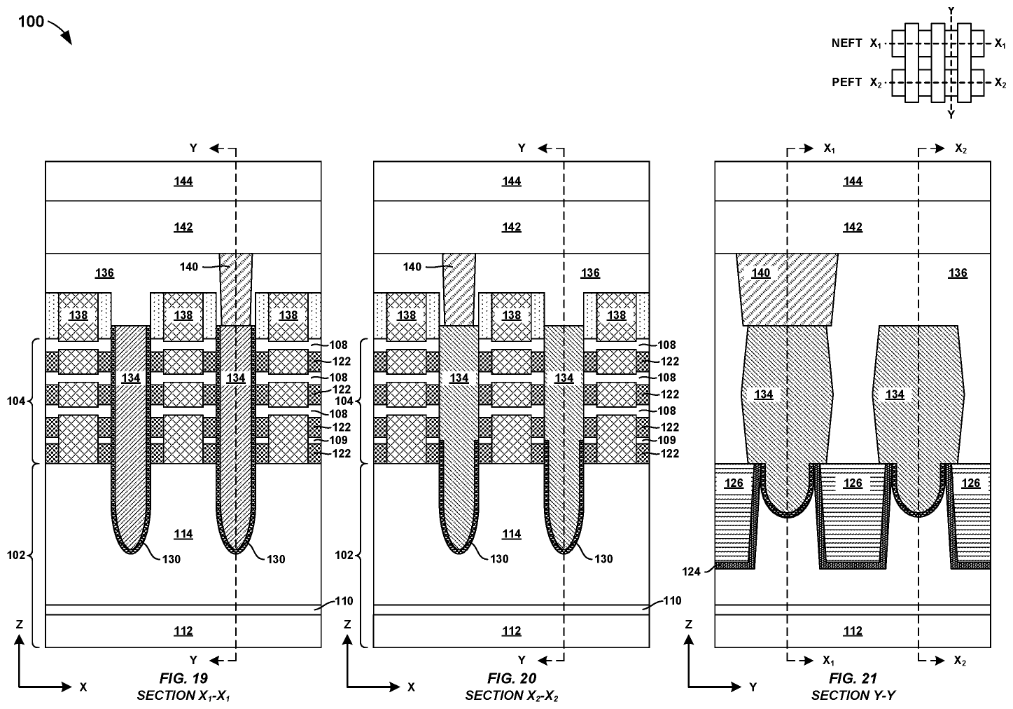

Referring now to FIGS. 19, 20, and 21, the structure 100 is shown after forming source drain contacts 140, middle-of-line and back-end-of-line 142, and securing a carrier wafer 144 according to an embodiment of the invention. FIG. 19 depicts a cross-sectional view of the structure 100 taken along line X₁-X₁, FIG. 20 depicts a cross-sectional view of the structure 100 taken along line X₂-X₂, and FIG. 21 depicts a cross-sectional view of the structure 100 taken along line Y-Y.

First, additional interlayer dielectric material is deposited according to known techniques. The dielectric layer 136 illustrated in the figures includes the additional interlayer dielectric material.

Next, portions of the dielectric layer 136 are removed to expose the source drain regions 134. Next, the openings are filled with a conductive material to form the source drain contacts 140 according to known techniques. The source drain contacts 140 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, the source drain contacts 140 do not contact the gate spacers 120. In other embodiments, the source drain contacts 140 are self-aligned to the gate spacers 120, and thus may be referred to as self-aligned contact structures.

Finally, the middle-of-line and back-end-of-line 142 (hereinafter MOL/BEOL 142) is formed and carrier wafer 144 is secured to a top of the structure 100 according to an embodiment of the invention. After forming the source drain contacts 140, the MOL/BEOL 142 is subsequently formed according to known techniques. Next, the carrier wafer 144 is attached, or removably secured, to the MOL/BEOL 142. In general, and not depicted, the carrier wafer 144 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 144 according to known techniques.

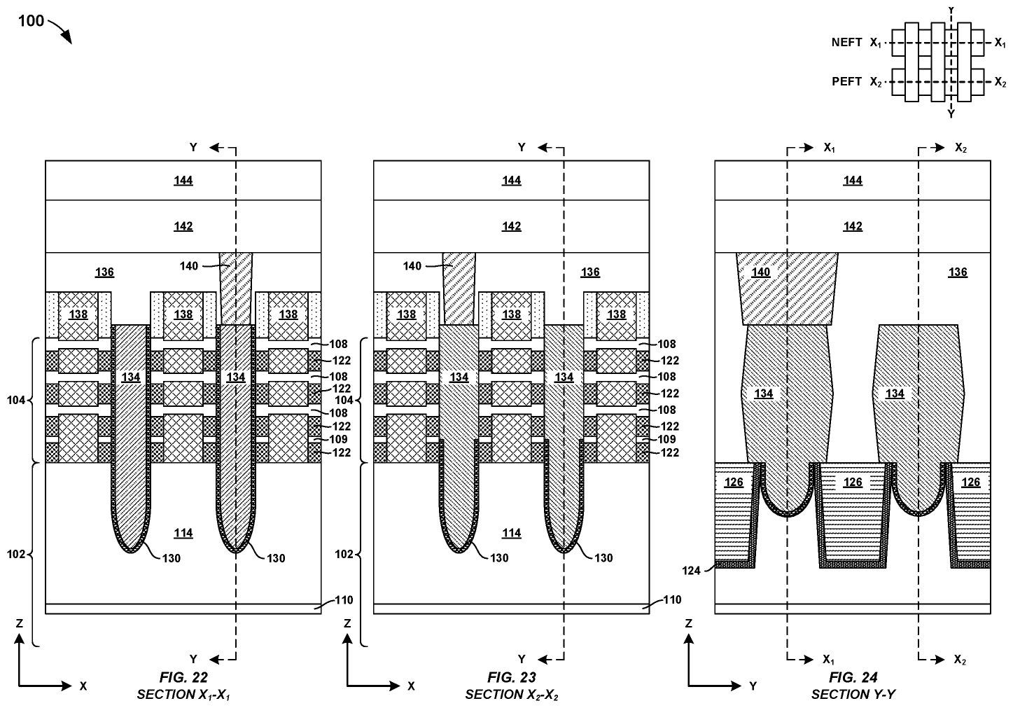

Referring now to FIGS. 22, 23, and 24, the structure 100 is shown after flipping the assembly and recessing the substrate 102 according to an embodiment of the invention. FIG. 22 depicts a cross-sectional view of the structure 100 taken along line X₁-X₁, FIG. 23 depicts a cross-sectional view of the structure 100 taken along line X₂-X₂, and FIG. 24 depicts a cross-sectional view of the structure 100 taken along line Y-Y.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

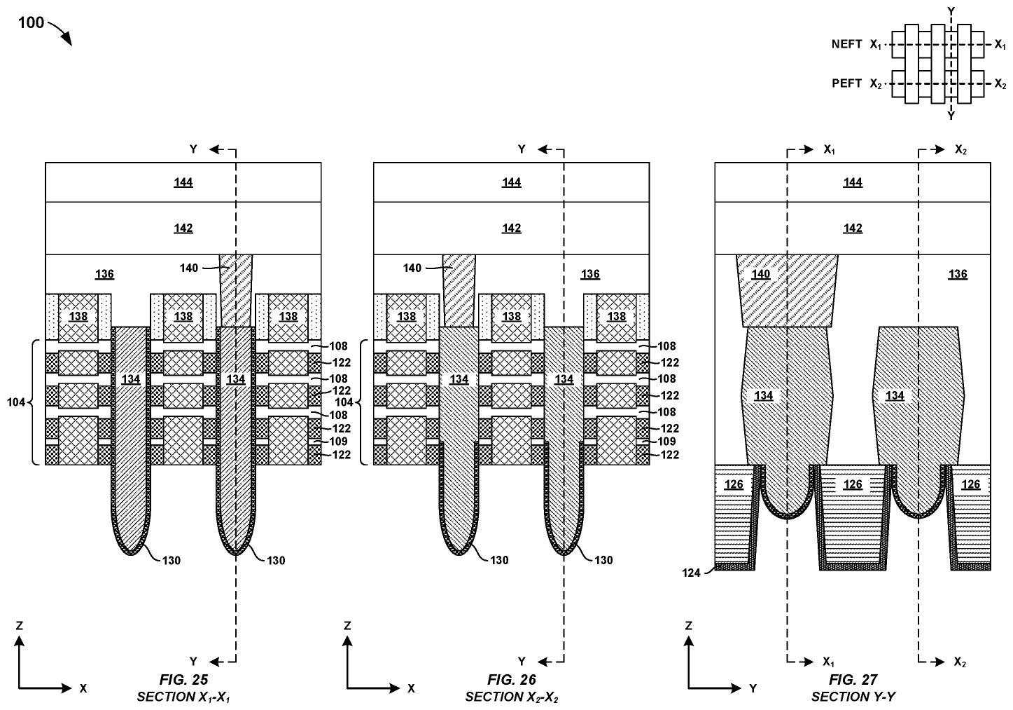

Referring now to FIGS. 25, 26, and 27, the structure 100 is shown after removing and recessing remaining portions of the substrate 102 according to an embodiment of the invention.

FIG. 25 depicts a cross-sectional view of the structure 100 taken along line X₁-X₁, FIG. 26 depicts a cross-sectional view of the structure 100 taken along line X₂-X₂, and FIG. 27 depicts a cross-sectional view of the structure 100 taken along line Y-Y.

First, the etch stop layer 110 is selectively removed and the top semiconductor layer 114 is recessed according to known techniques. Specifically, the etch stop layer 110 is removed selective to the top semiconductor layer 114 and the top semiconductor layer 114 is removed selective to the liners 130, the inner spacers 122, the gate structures 138, and the STI regions, as illustrated. Significant to the embodiments disclosed herein, the liners 130 protect the source drain regions 134 during substrate removal.

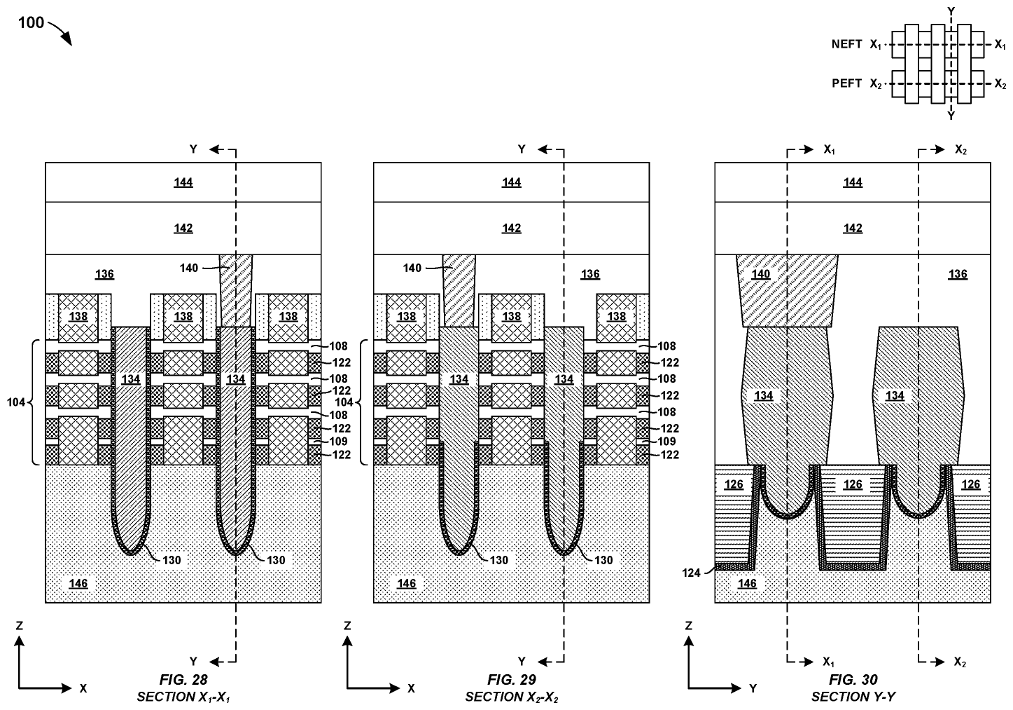

Referring now to FIGS. 28, 29, and 30, the structure 100 is shown after forming a backside dielectric layer 146 according to an embodiment of the invention. FIG. 28 depicts a cross-sectional view of the structure 100 taken along line X₁-X₁, FIG. 29 depicts a cross-sectional view of the structure 100 taken along line X₂-X₂, and FIG. 30 depicts a cross-sectional view of the structure 100 taken along line Y-Y.

The backside dielectric layer 146 is deposited according to known techniques. Specifically, a backside dielectric material is blanket deposited across the structure 100. The backside dielectric layer 146 completely covers exposed portions of the liners 130. Additionally, the backside dielectric layer 146 also surrounds portions of the source drain regions 134 protruding or extending below the nanosheet stacks 104, as illustrated. In all cases, the liners 130 remain and physically separate the backside dielectric layer 146 from the source drain regions 134. After deposition, known chemical mechanical polishing may be used to remove excess portions of the backside dielectric material from bottom surfaces of the structure 100.

The backside dielectric layer 146 can include any known dielectric material including, for example, those disclosed above with respect to the dielectric layer 136.

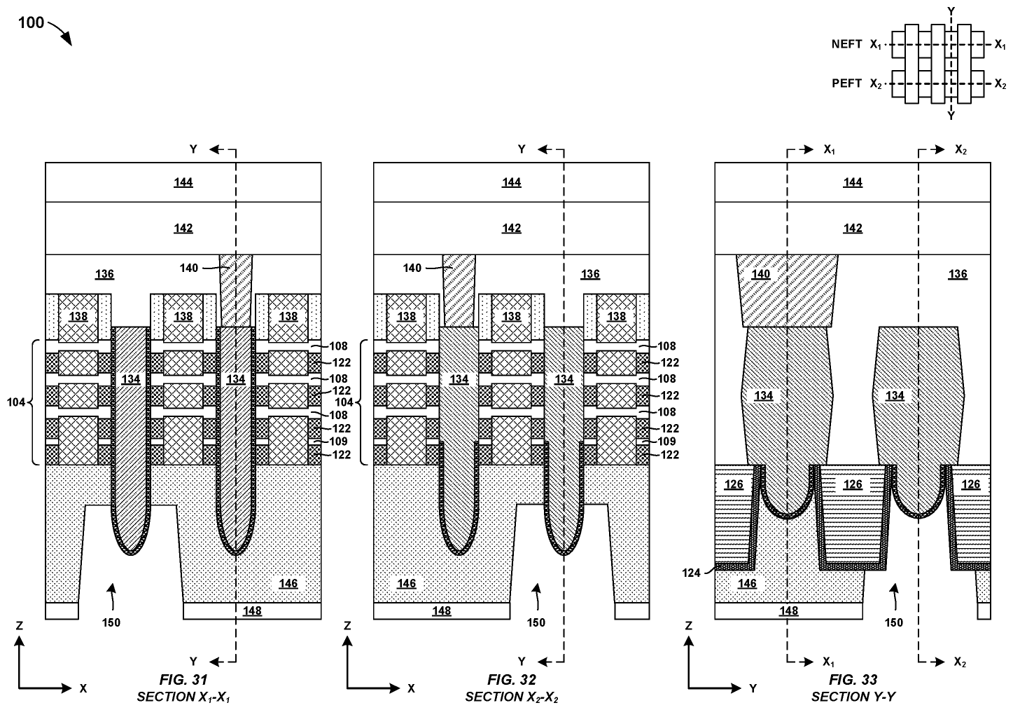

Referring now to FIGS. 31, 32, and 33, the structure 100 is shown after forming a mask 148 and removing portions of the backside dielectric layer 146 to form backside contact trenches 150 according to an embodiment of the invention. FIG. 31 depicts a cross-sectional view of the structure 100 taken along line X₁-X₁, FIG. 32 depicts a cross-sectional view of the structure 100 taken along line X₂-X₂, and FIG. 33 depicts a cross-sectional view of the structure 100 taken along line Y-Y.

First, the mask 148 is deposited and subsequently patterned to expose certain portions of the structure 100 according to known techniques. The mask 148 can be an organic planarization layer (OPL) or a layer of material that is capable of being planarized or etched by known techniques. In an embodiment, for example, the mask 148 can be an amorphous carbon layer able to withstand subsequent processing temperatures. The mask 148 can preferably have a thickness sufficient to cover existing structures. After depositing the mask 148, a dry etching technique is applied to pattern or recess the mask 148 according to known techniques. The mask 148 is patterned consistent with a size and a location of subsequently formed backside contact structures. For example, after patterning the mask 148, portions of the structure 100 in contact regions are exposed, as illustrated. Specific to the embodiments disclosed herein, the mask 148 is patterned selective to the backside dielectric layer 146.

Exposed portions of the backside dielectric layer 146 are then selectively removed to form the backside contact trenches 150 according to known techniques. Specifically, exposed portions of the backside dielectric layer 146 are removed using known etching techniques suitable to remove dielectric materials selective to the mask 148 and the liners 130, as illustrated. In an embodiment, the exposed portions of the backside dielectric layer 146 are removed using an anisotropic etch such as, for example, reactive ion etching. After removing the exposed portions of the backside dielectric layer 146, portions of the liners 130 are exposed, as illustrated. Significant to the embodiments disclosed herein, etching stops on the liners 130. As such, the liners 130 function as an etch stop and protect the source drain regions 134 during etching of the backside contact trenches 150.

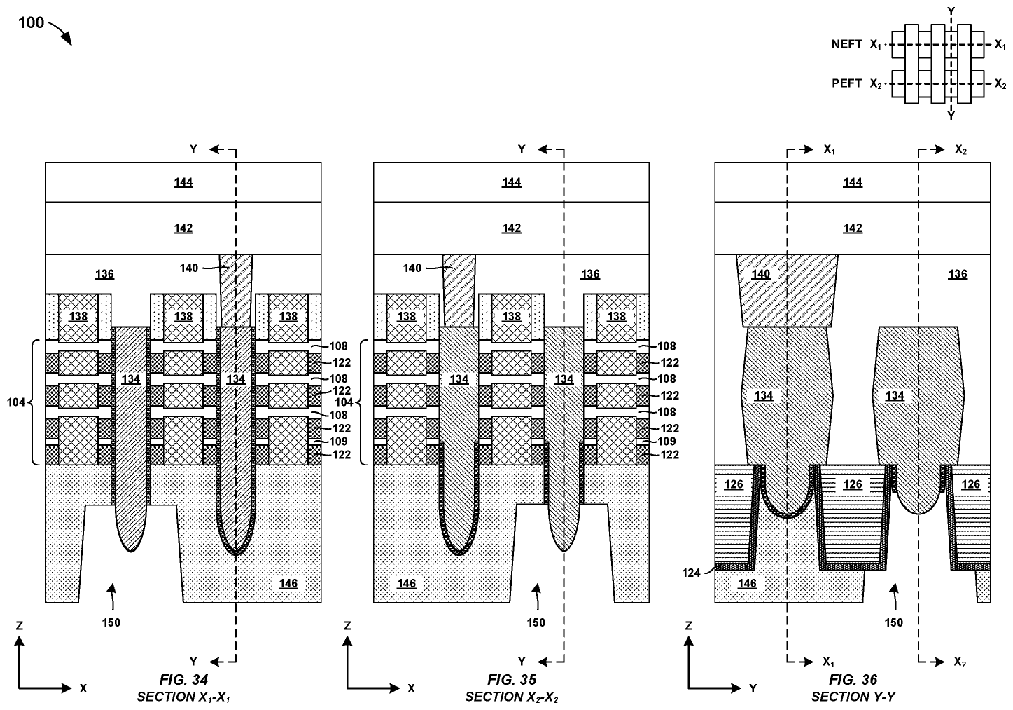

Referring now to FIGS. 34, 35, and 36, the structure 100 is shown after removing portions of the liner 130 according to an embodiment of the invention. FIG. 34 depicts a cross-sectional view of the structure 100 taken along line X₁-X₁, FIG. 35 depicts a cross-sectional view of the structure 100 taken along line X₂-X₂, and FIG. 36 depicts a cross-sectional view of the structure 100 taken along line Y-Y.

Portions of the liners 130 exposed within the backside contact trenches 150 are selectively removed according to known techniques. Specifically, the portions of the liners 130 exposed within the backside contact trenches 150 are etched or removed selective to the source drain regions 134, the backside dielectric layer 146, and the STI regions. The portions of the liners 130 exposed within the contact trenches 152 can be removed using compatible selective dryetch or wet etching techniques. After etching, other portions of the liners 130 otherwise not exposed within the backside contact trenches 150 remain, as illustrated. Although removing the liners 130 is not critical, doing so maximizes contact volume and ensures a low resistance electrical connection between thew source drain regions 134 and the subsequently formed backside contact structures.

After removing portions of the liners 130, exposed portions of the source drain regions 134 are treated by a pre-silicide clean according to known techniques. In at least one embodiment, for example, a Siconi preclean is used to treat the source drain regions 134 prior to metal deposition and silicide formation.

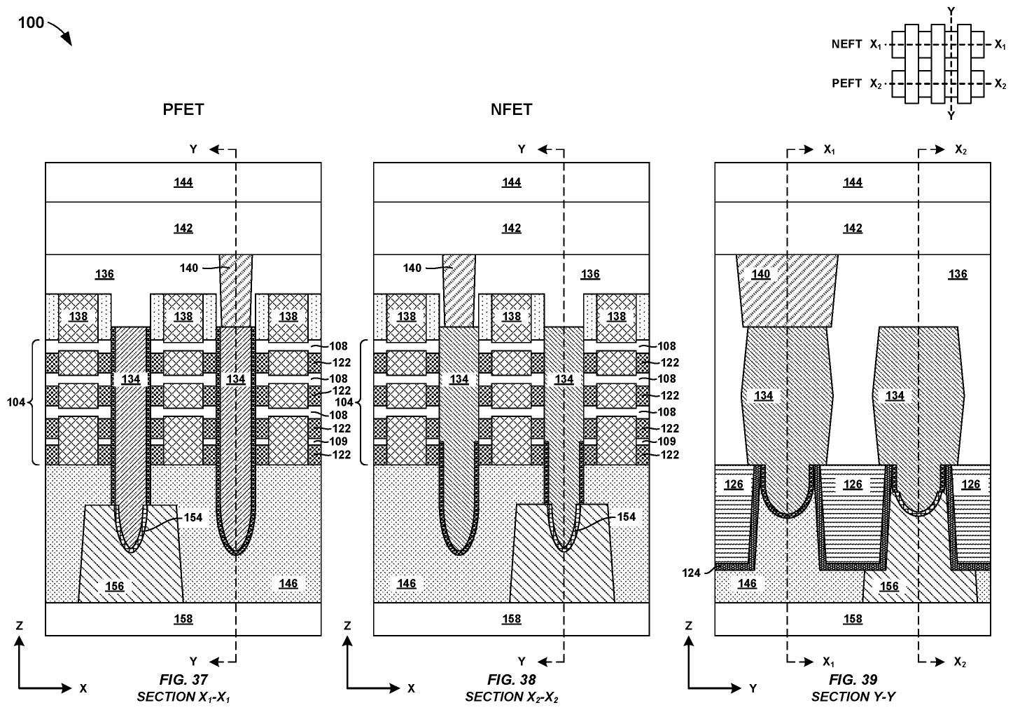

Referring now to FIGS. 37, 38, and 39, the structure 100 is shown after forming silicide layers 154, backside contact structures 156, and backside wiring layers 158 according to an embodiment of the invention. FIG. 37 depicts a cross-sectional view of the structure 100 taken along line X₁-X₁, FIG. 38 depicts a cross-sectional view of the structure 100 taken along line X₂-X₂, and FIG. 39 depicts a cross-sectional view of the structure 100 taken along line Y-Y.

First, the silicide layers 154 are formed on surfaces of the source drain regions 134 exposed within the contact trenches 152 according to known techniques. In doing so, a metal alloy layer (not shown) is deposited uniformly over the entire structure 100. The metal alloy layer may be formed using conventional deposition techniques including, but not limited to: chemical vapor deposition (CVD), plasma-assisted CVD, high-density chemical vapor deposition (HDCVD), plating, sputtering, evaporation, and chemical solution deposition. Deposition of the metal alloy layer may continue until an initial thickness sufficient to produce a resulting silicide that is approximately 4 nm thick.

In an embodiment, the metal alloy layer may include titanium or a titanium-based alloy. In an embodiment, the metal alloy layer may alternatively include a nickel-platinum (NiPt) alloy. In yet another embodiment, the metal alloy layer may include NiPd, NiRe, TiTa, TiNb, or Co. Other metal or alloying additives that can be optionally present in the metal alloy layer may include Pd, Rh, V, Cr, Zr, Nb, Mo, Ht, Ta, W, or Re.

Next, the backside contact trenches 152 are filled with a conductive material to form the backside contact structures 156 according to known techniques. The backside contact structures 156 may include any suitable conductive material, such as, for example, copper, ruthenium, aluminum, tungsten, cobalt, or alloys thereof.

After, excess conductive material can be polished using known techniques until bottommost surfaces of the backside contact structures 156 are flush, or substantially flush, with bottommost surfaces of the backside dielectric layer 146, as illustrated. After polishing, bottommost surfaces of the backside contact structures 156 are substantially flat. It is noted, the backside contact structures 156 may include, for example, backside source drain contacts, as illustrated, as well as backside gate contacts (not shown). In all cases, portions of the source drain regions 134 protrude or extend into the backside contact structures 156 as illustrated. Said differently, a bottommost surface or point of the source drain regions 134 is below a topmost surface of the backside contact structures 156. Further, a transition or interface between the liners 130 and the silicide layers 154 will be at or adjacent to the topmost surface of the backside contact structures 156.

After forming the backside contact structures 156, the backside wiring layers 158 are subsequently formed according to known techniques. The backside wiring layers 158 typically include at least backside power rails (not shown) and a backside power delivery network (not shown).

According to the embodiment illustrated in FIGS. FIGS. 37-39, the transistor structures represented by the structure 100 have some distinctive notable features. For instance, the structure 100 includes the source drain regions 134 extending beneath the channel nanosheets 108 into a backside dielectric layer 146.

It is further reiterated, the liners 130 in the PFET regions physically separate the source drain regions 134 from the channel nanosheets 108, where in the NFET regions the source drain regions 134 directly contact the channel nanosheets 108. This is a direct result of recessing the liners 130 as described above with reference to FIGS. 5-7. Furthermore, doing so enables co-integration of PFET regions and NFET regions in a single process flow.

In all cases, the liners 130 physically separate all source drain regions 134 from the backside dielectric layer 146. For example, in regions without the backside contact structures 156, the liners 130 completely surround the bottom portions of the source drain regions 134. For example, in regions with the backside contact structures 156 only a portion of the source drain regions 134 between the nanosheet stacks 104 and the backside contact structures 156 will be completely surrounded by the liners 130.

With continued reference to FIGS. 37-39, the structure 100 includes both the source drain contacts 140 arranged in the middle-of-the-line and the backside contact structures 156, as illustrated. Both the source drain contacts 140 and the backside contact structures 156 may be used in either the PFET region or the NFET region depending on design.

With continued reference to FIGS. 37-39, and according to an embodiment, the structure 100 include source drain regions arranged between channel nanosheets, where the source drain regions extend below a bottommost channel nanosheet into a backside dielectric layer, a liner surrounding at least a portion of the source drain regions, and backside contact structures in electrical contact with the source drain regions.

With continued reference to FIGS. 37-39, and according to an embodiment, the structure further includes a silicide arranged between and physically separating the source drain regions from the backside contact structures.

With continued reference to FIGS. 37-39, and according to an embodiment, the structure further includes shallow trench isolation regions, where the source drain regions extend below a topmost surface of the shallow trench isolation regions, and the liner physically separates the source drain regions from the shallow trench isolation regions.

With continued reference to FIGS. 37-39, and according to an embodiment, the source drain regions further comprise PFET source drain regions and NFET source drain regions, where a first top surface of the liner is substantially flush with a topmost surface of the PFET source drain regions, and where a second top surface of the liner is below a topmost surface of the NFET source drain regions.

With continued reference to FIGS. 37-39, and according to an embodiment, a topmost surface of the liner in a PFET region is above a topmost channel nanosheet, and where a topmost surface of the liner in an NFET region is below the bottommost channel nanosheet.

With continued reference to FIGS. 37-39, and according to an embodiment, a bottom surface of the liner directly contacts a top surface of the backside contact structure.

With continued reference to FIGS. 37-39, and according to an embodiment, the liner is silicon germanium.

With continued reference to FIGS. 37-39, and according to an embodiment, the structure 100 includes a first source drain region arranged between first channel nanosheets, and a second source drain region arranged between second channel nanosheets, a first backside contact structure in electrical contact with the first source drain region and a second backside contact structure in electrical contact with the second source drain region, a first liner surrounding a portion of the first source drain region and a second liner surrounding a portion of the second source drain region, and where the first liner is arranged between and physically separates the first source drain region from the first channel nanosheets, and where the second source drain region directly contacts the second channel nanosheets.

With continued reference to FIGS. 37-39, and according to an embodiment, the structure further includes a first silicide arranged between and physically separating the first source drain region from the first backside contact structure, and a second silicide arranged between and physically separating the second source drain region from the second backside contact structure.

With continued reference to FIGS. 37-39, and according to an embodiment, the structure further includes shallow trench isolation regions, where both the first source drain region and the second source drain region extend below a topmost surface of the shallow trench isolation regions, the first liner physically separates the first source drain region from the shallow trench isolation regions, and the second liner physically separates the second source drain region from the shallow trench isolation regions.

With continued reference to FIGS. 37-39, and according to an embodiment, the first source drain region further comprises a PFET source drain region and the second source drain region further comprises an NFET source drain region, where a top surface of the first liner is substantially flush with a topmost surface of the PFET source drain region, and where a top surface of the second liner is below a topmost surface of the NFET source drain region.

With continued reference to FIGS. 37-39, and according to an embodiment, a topmost surface of the first liner in a PFET region is above a topmost channel nanosheet of the first channel nanosheets, and where a topmost surface of the second liner in an NFET region is below a bottommost channel nanosheet of the second channel nanosheets.

With continued reference to FIGS. 37-39, and according to an embodiment, bottom surfaces of the first liner directly contact a top surface of the first backside contact structure, and bottom surfaces of the second liner directly contact a top surface of the second backside contact structure.

With continued reference to FIGS. 37-39, and according to an embodiment, both the first liner and the second liner are silicon germanium.

With continued reference to FIGS. 37-39, and according to an embodiment, the structure 100 includes source drain regions arranged between channel nanosheets, where the source drain regions extend beneath the channel nanosheets into a backside dielectric layer, a liner arranged between and physically separating the source drain regions from the backside dielectric layer, and backside contact structures in electrical contact with the source drain regions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
source drain regions arranged between channel nanosheets, wherein the source drain regions extend below a bottommost channel nanosheet into a backside dielectric layer;
a liner surrounding at least a portion of the source drain regions; and
backside contact structures in electrical contact with the source drain regions.

2. The semiconductor structure according to claim 1, further comprising:
a silicide arranged between and physically separating the source drain regions from the backside contact structures.

3. The semiconductor structure according to claim 1, further comprising:
shallow trench isolation regions, wherein the source drain regions extend below a topmost surface of the shallow trench isolation regions, and the liner physically separates the source drain regions from the shallow trench isolation regions.

4. The semiconductor structure according to claim 1, wherein the source drain regions further comprise PFET source drain regions and NFET source drain regions, wherein a first top surface of the liner is substantially flush with a topmost surface of the PFET source drain regions, and wherein a second top surface of the liner is below a topmost surface of the NFET source drain regions.

5. The semiconductor structure according to claim 1, wherein a topmost surface of the liner in a PFET region is above a topmost channel nanosheet, and wherein a topmost surface of the liner in an NFET region is below the bottommost channel nanosheet.

6. The semiconductor structure according to claim 1, wherein a bottom surface of the liner directly contacts a top surface of the backside contact structure.

7. The semiconductor structure according to claim 1, wherein the liner is silicon germanium.

8. A nanosheet semiconductor structure comprising:
a first source drain region arranged between first channel nanosheets, and a second source drain region arranged between second channel nanosheets;
a first backside contact structure in electrical contact with the first source drain region and a second backside contact structure in electrical contact with the second source drain region;
a first liner surrounding a portion of the first source drain region and a second liner surrounding a portion of the second source drain region; and
wherein the first liner is arranged between and physically separates the first source drain region from the first channel nanosheets, and wherein the second source drain region directly contacts the second channel nanosheets.

9. The semiconductor structure according to claim 8, further comprising:
a first silicide arranged between and physically separating the first source drain region from the first backside contact structure; and
a second silicide arranged between and physically separating the second source drain region from the second backside contact structure.

10. The semiconductor structure according to claim 8, further comprising:
shallow trench isolation regions, wherein both the first source drain region and the second source drain region extend below a topmost surface of the shallow trench isolation regions, the first liner physically separates the first source drain region from the shallow trench isolation regions, and the second liner physically separates the second source drain region from the shallow trench isolation regions.

11. The semiconductor structure according to claim 8, wherein the first source drain region further comprises a PFET source drain region and the second source drain region further comprises an NFET source drain region, wherein a top surface of the first liner is substantially flush with a topmost surface of the PFET source drain region, and wherein a top surface of the second liner is below a topmost surface of the NFET source drain region.

12. The semiconductor structure according to claim 8, wherein a topmost surface of the first liner in a PFET region is above a topmost channel nanosheet of the first channel nanosheets, and wherein a topmost surface of the second liner in an NFET region is below a bottommost channel nanosheet of the second channel nanosheets.

13. The semiconductor structure according to claim 8, wherein bottom surfaces of the first liner directly contact a top surface of the first backside contact structure, and bottom surfaces of the second liner directly contact a top surface of the second backside contact structure.

14. The semiconductor structure according to claim 1, wherein both the first liner and the second liner are silicon germanium.

15. A nanosheet semiconductor structure comprising:
source drain regions arranged between channel nanosheets, wherein the source drain regions extend beneath the channel nanosheets into a backside dielectric layer;
a liner arranged between and physically separating the source drain regions from the backside dielectric layer; and
backside contact structures in electrical contact with the source drain regions.

16. The semiconductor structure according to claim 15, further comprising:
a silicide arranged between and physically separating the source drain regions from the backside contact structures.

17. The semiconductor structure according to claim 15, further comprising:
shallow trench isolation regions, wherein the source drain regions extend below a topmost surface of the shallow trench isolation regions, and the liner physically separates the source drain regions from the shallow trench isolation regions.

18. The semiconductor structure according to claim 15, wherein the source drain regions further comprise NFET source drain regions and PFET source drain regions, wherein a first top surface of the liner is substantially flush with a topmost surface of the PFET source drain regions, and wherein a second top surface of the liner is below a topmost surface of the NFET source drain regions.

19. The semiconductor structure according to claim 15, wherein a topmost surface of the liner in a PFET region is above a topmost channel nanosheet, and wherein a topmost surface of the liner in an NFET region is below a bottommost channel nanosheet of the channel nanosheets.

20. The semiconductor structure according to claim 15, wherein a bottom surface of the liner directly contacts a top surface of the backside contact structure.
